(19) United States
(12) Patent Application Publication
(10) Pub. No.: US 2007/0057299 A1
(43) Pub. Date: Mar. 15, 2007

(54) SYSTEMS AND METHODS HAVING A METAL-SEMICONDUCTOR-METAL (MSM) PHOTODETECTOR WITH BURIED OXIDE LAYER

(75) Inventor: Torsten Wipiejewski, Hong Kong (CN)

Correspondence Address: DALLAS OFFICE OF FULBRIGHT & JAWORSKI L.L.P., 2200 ROSS AVENUE, SUITE 2800, DALLAS, TX, 75201-2784, US

(73) Assignee: SAE Magnetics (H.K.) Ltd., Hong Kong (CN)

(21) Appl. No.: 11/555,966

(22) Filed: Nov. 2, 2006

Related U.S. Application Data
(62) Division of application No. 10/932,879, filed on Sep. 2, 2004.
(60) Provisional application No. 60/500,656, filed on Sep. 5, 2003.

(51) Int. Cl. H01L 31/062

(52) U.S. Cl. 257/293

(57) ABSTRACT

Described herein is an MSM photodetector device wherein a dielectric layer is positioned between the absorbing layer and the substrate layer in order to decrease the device capacitance and thereby increasing the photodetector bandwidth. The dielectric layer increases the photodetector efficiency and blocks slow moving carriers from the high field drift region. The dielectric layer may be an oxide layer formed by one of wet thermal oxidation of AlGaAs, ion implantation, or wafer bonding with subsequent substrate removal.

### RELATED APPLICATIONS

This application claims priority to U.S. Patent Application Ser. No. 60/500,656, entitled “METAL-SEMICONDUCTOR-METAL (MSM) PHOTODETECTOR WITH BURIED OXIDE LAYER,” filed Sep. 5, 2003, is related to co-pending and commonly assigned U.S. Patent Application Ser. No. [Attorney Docket Number 67269-P002US-1 0410083], entitled “FREE SPACE MSM PHOTODETECTOR ASSEMBLY,” the disclosure of which is hereby incorporated herein by reference.

### TECHNICAL FIELD

This application relates in general to optical communication, and in specific to systems and methods involving an MSM photodetector.

### BACKGROUND OF THE INVENTION

Metal-semiconductor-metal (MSM) photodetectors have been previously employed for light detection in fiber optics systems FIG. 1 illustrates a typical design of an MSM photodetector 100 in a cross-sectional view. An absorbing layer 101 of thickness t is located on top of a substrate 102. The absorbing layer typically comprises undoped semiconducting material, and the substrate typically comprises semi-insulating semiconducting material. For applications in the 850 nm wavelength range or lower, applications will typically use variants of GaAs for both layers. Metal electrode lines, or fingers, 103 are deposited on top of the absorbing layer 101. Light 104 is incident onto the photodetector 100 and reaches the absorbing layer 101 between the metal lines 103, and creates electron-hole pairs 105 in absorbing layer 101. If a voltage is applied between the electrodes 103, namely (V+ to V−), the carriers are accelerated in the electrical field between the electrodes 103. As carriers 105 travel in the semiconductor between electrodes 103, they will influence a current in outside electrical circuit 106. Thus, incoming light 104 is converted into electrical current in circuit 106.

The field between the electrodes 103 is, under normal operation, high enough that carriers 105 travel at the saturation drift velocity νₛ. For typical III-V semiconductors like GaAs, ν_{S} is approximately

$${υ}_{S} = {10}^{7} \frac{cm}{s} .$$

The electrodes have an individual width w, and the spacing in between s, and the resulting structure will form a capacitor. The capacitance of the structure is equivalent to an ideal parallel plate capacitor that has a plate separation of h_{eff}.

FIG. 2 depicts a top down view 200 of the MSM photodetector of FIG. 1. The diameter of the active area is D, and the total length of all metal electrodes 103 combined is Ls. Metal electrodes 103 form an inter-digit finger structure to cover the active area, and alternate in connection to positive electrode 201 and the negative electrode 202, such that each electrode 103 is attached to one of electrode bondpads 201, 202. Light falling onto metal electrodes 103 will not reach the absorbing layer and will not detected. Although smaller width electrodes 103 provide the advantage of blocking less of the incoming light, they are frequently more difficult to fabricate.

A typical fabrication process for photodetector 100 may include epitaxially growing absorbing layer 101 onto substrate 102. Absorbing layer 101 should have a low background doping concentration in order to create a free-carrier depletion region between the metal electrodes using a low bias voltage. The epitaxial growth process may be molecular beam epitaxy (MBE), metal organic vapor phase epitaxy (MOVPE), chemical vapor deposition (CVD), or other similar process. A traditional lift-off technique can be used for the deposition of the metal electrodes 103 forming a Schottky barrier to absorption layer 101. A typical photodetector 100 will have platinum electrodes 103 (with thickness 100 nm) that have a gold layer (thickness 100 nm) on top (i.e. the side away from the absorbing layer 101) for easy bonding and a thin (10 nm) titanium layer beneath (i.e. the side adjacent to the absorbing layer 101) to improve adhesion to the semiconductor. The larger area bondpads for electrodes 201 and 202 may be formed in a separate metal deposition process.

A dielectric insulating layer (not shown) can also be deposited between the bondpad metalization 201, 202 and the absorbing layer 101 to reduce leakage current. Finally, the photodetector 100 can be covered with an anti-reflection (AR) coating (not shown) to reduce light reflection at the semiconductor-air interface. The refractive index of the AR coating should be the square-root of the refractive index of the semiconductor and have a quarter-wavelength thickness. A common AR material to use for GaAs is Si₃N₄ with an index of refraction of approximately 1.9.

### BRIEF SUMMARY OF THE INVENTION

Described herein is an MSM photodetector device wherein a dielectric layer is positioned between the absorbing layer and the substrate layer in order to decrease the device capacitance and thereby increasing the photodetector bandwidth. The dielectric layer increases the photodetector efficiency and blocks slow moving carriers from the high field drift region. The dielectric layer may be an oxide layer formed by one of wet thermal oxidation of AlGaAs, ion implantation, or wafer bonding with subsequent substrate removal.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention as set forth in the appended claims. The novel features which are believed to be characteristic of the invention, both as to its organization and method of operation together with further objects and advantages will be better understood from the following description when considered in connection with the accompanying FIGURES. It is to be expressly understood, however, that each of the FIGURES is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 depicts a side cross-sectional view of a typical MSM photodetector;

FIG. 2 depicts a top view of the MSM photodetector of FIG. 1;

FIG. 3 depicts a graph of the drift time constant and RC time constant as a function of electrode spacing for the MSM photodetector of FIG. 1;

FIG. 4 depicts the electrical field lines in the MSM photodetector of FIG. 1;

FIG. 5 depicts an example of a MSM photodetector having an intermediate layer according to embodiments of the invention; and

FIG. 6 depicts another example of a MSM photodetector having an intermediate layer according to other embodiments of the invention.

### DETAILED DESCRIPTION OF THE INVENTION

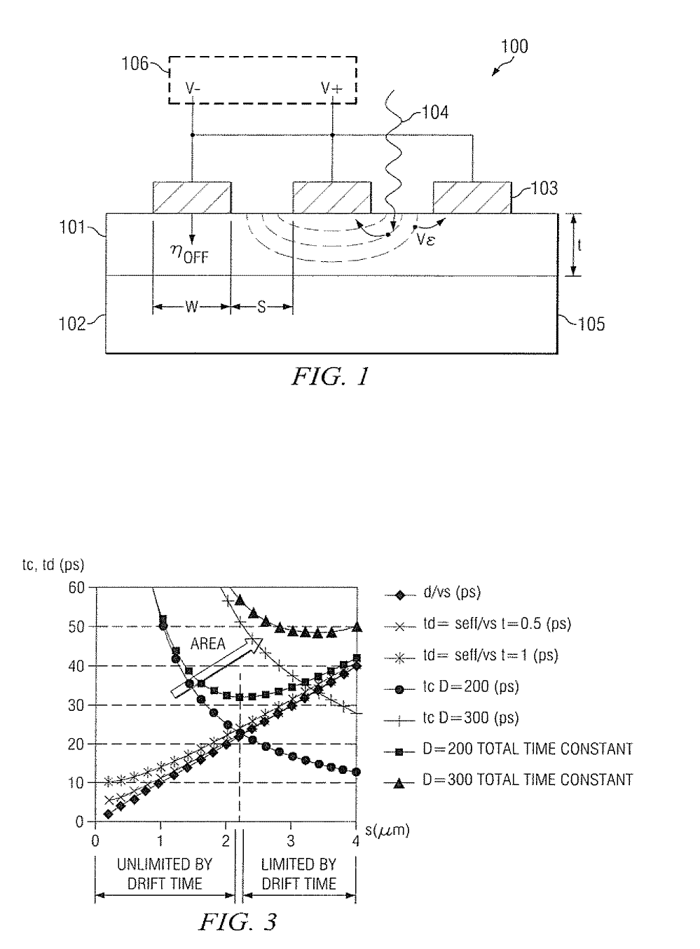

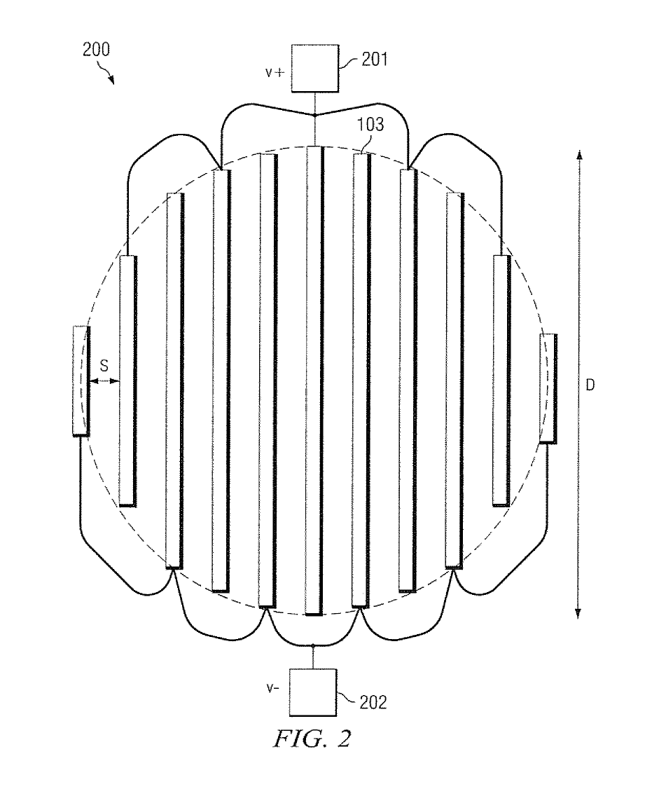

The bandwidth of a system using a MSM photodetector will be limited by the speed and the sensitivity of that photodetector. The speed of photodetector 100 in FIG. 1 is limited by the drift time of photo-generated carriers 105, as well as the capacitance associated with the device itself. The spacing between electrodes 103 and the area of photodetector 100, in part, determines the drift time and the capacitance, thus both need to be optimized in order to achieve as large a bandwidth as possible for a system.

FIG. 3 depicts a graph of the drift time constant and RC time constant as a function of electrode spacing for the MSM photodetector 100 of FIG. 1. The drift time increases (linearly) with increasing electrode separation due to the longer distance that the carrier has to travel with saturation drift velocity νₛ. For a small spacing of the electrode, e.g. one micron, the average drift time increases with the thickness of the absorbing layer. In FIG. 3, results are illustrated for an absorbing layer thickness of 0.5 μm and 1 μm, respectively. The time constants are independent of the electrode finger width w, but are dependent on area. Thus larger finger spacing results in a drift-time related speed limitation and also requires a higher bias voltage.

For smaller finger spacing the capacitance is the speed-limiting factor of the MSM photodetector. Moreover, the RC time constant decreases with the electrode separation, because the capacitance decreases with the spacing or separation. As can be seen in FIG. 3, the RC time constant is larger for larger diameter devices as shown for D=200 μm and D=300 μm, respectively. Thus, the resulting time constant, determined from the geometrical average of drift time and RC time, determines the speed of the MSM photodetector and exhibits a minimum for a certain spacing.

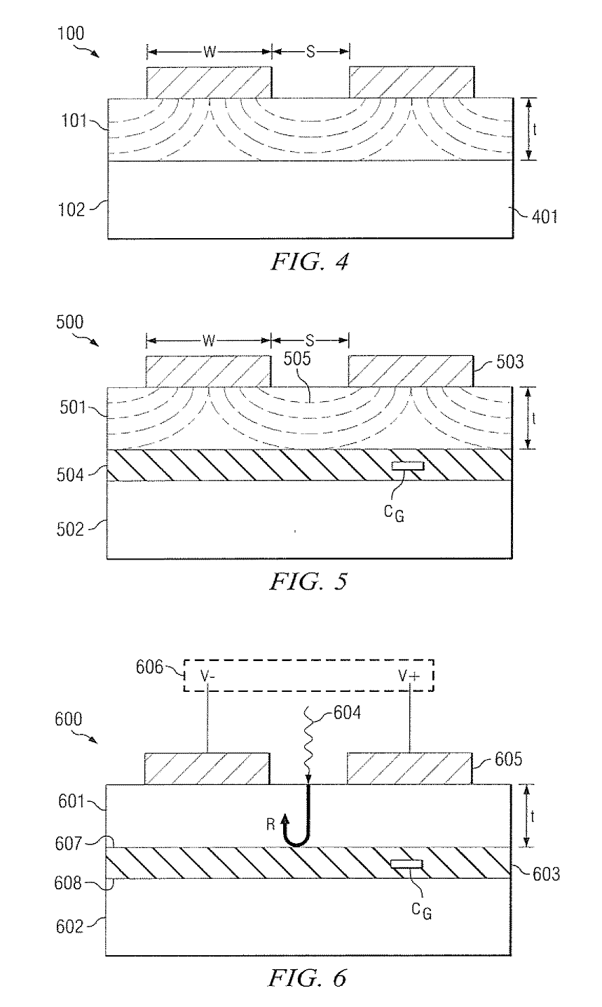

FIG. 4 depicts the electrical field lines 401 in the MSM photodetector 100 of FIG. 1. The electrical field 104 extends through absorbing layer 101 and into substrate 102. The space 402 above the semiconductor layer 101 exhibits only a weak field, because the dielectric constant of air (or the AR coating) is very small compared to the dielectric constant of absorbing layer 101 (∈_{R}). For example, the dielectric constant of GaAs is approximately thirteen, compared to one for air.

Minimizing the bandwidth limiting factors in the size and spacing of electrodes 103 results in minimizing the drift time of photo-generated carriers between the metal electrodes by minimizing the distance between electrodes 103. However, the smaller the spacing between the metal electrodes, the larger the capacitance, and a large capacitance will limit the speed of the photodetector in the electrical circuit. The so-called RC-time constant is calculated using

$${t}_{c} = \frac{{R}_{L} {ɛɛ}_{o} {A}^{*}}{s} ,$$

where R_{L} is the electrical load resistance in the outside circuit (typically 50 Ohms), ∈ is the average dielectric constant of the material between the electrodes, ∈ₒ is the natural dielectric constant, A* is the effective area between the electrodes, and s is the electrode spacing. The calculation of the RC-time constant for a MSM photodetector is modified from other time constant calculations by using the effective area A* instead of A. The total length of all fingers of the MSM photodetector is Ls and the diameter is D. The effective area is defined as

$${A}^{*} = heff \cdot Ls = \frac{heff}{s + w} \frac{π}{4} {D}^{2} = \frac{heff}{s + w} A .$$

Thus, the effective area is the actual physical area reduced by the factor heff/(s+w). The RC-time constant can be rewritten as:

$${t}_{c} = \frac{{R}_{L} {ɛɛ}_{o}}{s} \frac{heff}{s + w} A .$$

The effective height heff corresponds to a parallel plate capacitor that would have the same capacitance C as the MSM electrode configuration, and can be calculated numerically. For spacing s equal or larger than the width w (s>=w) the result is heff/(s+w)=0.28. Thus, the capacitance of the MSM detector is only 0.28 times the capacitance of a pin-diode with the same diameter. This gives the MSM photodetector a speed advantage for larger areas, where the speed is mainly limited by the RC-time constant.

Embodiments of the invention take advantage of the aspects discussed above by placing an intermediate layer between the substrate and the absorbing layer to improve the function of the photodetector. One embodiment reduces the capacitance of the photodetector and enables larger bandwidths by using an intermediate layer with a dielectric constant that is less than the dielectric constant of the absorbing layer. The difference in dielectric constants will concentrate the electric field lines in the absorbing layer and reduce the capacitance of the photodetector.

FIG. 5 depicts an example embodiment where MSM photodetector 500 has an intermediate layer 504 according to embodiments of the invention. The intermediate layer is located between absorbing layer 501 and substrate 502. Electrodes 103 are located on absorbing layer 501 and have a width w and spacing s. Although not shown in FIG. 5, alternating electrodes would be connected to one of a positive electrode and a negative electrode of a voltage source. The high dielectric constant of the absorbing layer 501 surrounded by lower dielectric constants of intermediate layer 504 and the causes electrical field 505 to be concentrated in absorbing layer 501.

The dielectric constant of the intermediate layer is preferably significantly lower than the dielectric constant of the absorbing layer. In a typical embodiment, the intermediate layer has a dielectric constant that is 0.25 to 0.75 of that of the absorbing layer, i.e. 0.25∈_{R}<=∈₁<=0.75∈_{R}, where ∈_{R} is the dielectric constant of the absorbing layer and ∈₁ is the dielectric constant of the intermediate layer. For example, if the absorbing layer may comprise GaAs, which has a dielectric constant of about 13, then the intermediate layer should have a dielectric constant of about 4-8. Intermediate layer 504 causes electric field 505 to be more uniform as compared to electric field 401 (of FIG. 4), resulting in a reduction in the average overall dielectric constant between the metal electrodes. A lower average dielectric constant produces a lower overall capacitance, and thus higher speed MSM photodetector devices.

Additional problem can also arise from traditional designs. For example, carriers that are generated deep within the semiconductor material can require a long time to reach the high electric field region between the electrodes close to the semiconductor surface. These deep carriers create a low-speed tail in the impulse response of the photodetector and are thus undesirable. By inserting a material with a high bandgap energy between the absorbing layer and the substrate, deep, low-speed carriers can be prevented from reaching the high field region. This solution can, however, limit the thickness of the absorbing layer and allow light that is not absorbed in absorbing layer 101 to penetrate through to the substrate. Carriers generated by these photons may be prevented from reaching the absorbing layer by the high bandgap material. Alternative embodiments use an intermediate that has a refractive index less than the refractive index in the absorbing layer. This difference in the refractive index will cause any light that has passed through the absorbing layer to be reflected back from the layer boundary. The reflected light is thus given further opportunity to react with the absorbing layer, thereby increasing the efficiency of the photodetector.

FIG. 6 depicts an alternative embodiment where MSM photodetector 600 has an intermediate layer 603 according to embodiments of the invention. Intermediate layer 603 is located between absorbing layer 601 and substrate 602, and has a thickness t. Electrodes 605 are located on absorbing layer 601, and alternating electrodes would be connected to one of a positive electrode and a negative electrode of a voltage source 606. In this example embodiment, intermediate layer 603 has a refractive index that is less than the refractive index of absorbing layer 601. This difference in the refractive indices forms reflection surface 607 at the boundary of absorbing layer 601 and intermediate layer 603. Reflection surface 607 reflects light that has passed through absorbing layer 601 back into absorbing layer 601. The reflect light may then has another opportunity to interact with absorbing layer 601 to form carriers which interact with the circuit 606. This would improve the overall photodetector efficiency and make the photodetector more sensitive for a given amount of light.

The refractive index of the intermediate layer should be significantly lower than the refractive index of the absorbing layer. In general, intermediate layer 603 should have a refractive index that is about 0.3 to 0.7 of that of absorbing layer 601, i.e. 0.3n_{R}<=n₁<=0.7n_{R}, where n_{R} is the index of refraction of absorbing layer 601 and n₁ is the index of refraction of the intermediate layer 603. For example, if absorbing layer 601 comprises GaAs, which has a refractive index of about 3.5, then intermediate layer 603 should have a refractive index in the range of about 1.5 to 2.

When intermediate layer having an refractive index as described above, a Fresnel reflection of about 10% occurs at reflection surface 607. Second reflection surface 608 is also formed between the boundary of intermediate layer 603 and substrate 602. About 10% of the light that passes through intermediate layer 603 will be reflected back into the intermediate layer 603 and impinge on the first reflection surface 607. Thus the interaction of the two reflection surfaces results in about 18% of the light being reflected back into absorbing layer 601. Multiple interfaces can enhance this effect further. Therefore about 18% or more of the light that is not absorbed in absorbing layer 601 on a first pass is reflected back into the absorbing layer.

Another embodiment of the invention involves an intermediate layer that has aspects of the embodiments shown in FIG. 5 and FIG. 6. In other words, the intermediate layer has both a dielectric constant that is less than the dielectric constant of the absorbing layer and a refractive index that is less than the refractive index of the absorbing layer.

Another embodiment of the invention may have the intermediate layer be non-conductive. This intermediate layer would provide a good barrier for any free carriers generated in the substrate, thus preventing them from reaching the high field region between the electrodes. This prevents the slow speed tails in the impulse response of the conventional photodetectors of the prior art. Such in intermediate layer may comprise an oxide layer.

Various methods may be used to fabricate the intermediate layer. For example if the intermediate layer is an oxide layer than one approach may be to oxidize a layer of AlGaAs that is grown during the epitaxial growth process between the absorbing layer and the substrate. In this approach, the fabrication starts with the deposition of the metal electrodes and the AR coating. Then a mesa structure is etched around the photodetector area to access the buried AlGaAs layer. The AlGaAs layer is laterally oxidized in a humid nitrogen atmosphere at about 400° C. The nitrogen is saturated with water vapor. The process converts AlGaAs to aluminum-gallium-oxide. Depending on temperature and distance to oxidize the process might take minutes to hours. Since AlGaAs with a high aluminum content of 90% or higher is much more reactive than GaAs, the absorbing layer remains basically unoxidized. Thus, the intermediate oxide layer may comprise AlGaAs with an aluminum content of 98% to 100%.

In another approach, instead of forming metal electrodes and bondpads first, a reverse process order is also possible. In this case, the AlGaAs layer is oxidized before the metal electrodes are deposited. An additional dielectric layer might be deposited on the wafer first to protect the absorbing layer during the oxidation process.

In another approach, holes may be etched into the semiconductor absorbing layer to access the buried AlGaAs instead of forming a mesa type structure.

Another approach may be to create the buried oxide layer by ion implantation of oxygen into the semiconductor wafer. This is used in the electronics industry to form silicon-on-insulator (SOI) circuits.

Another approach to form the oxide layer is to form on the semiconductor layer and then bond the wafer to another substrate. Various methods for bonding exist including epoxy bonding, anodic bonding, or wafer bonding. Afterwards the substrate of the original wafer is removed leaving the absorbing layer on top of the oxide layer bonded to the new substrate. At this stage the normal MSM photodetector wafer processing is employed to create the photodetector device(s).

Although the present invention and its advantages have been described in detail, it should be understood that various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one will readily appreciate from the disclosure, processes, machines, manufacture, compositions of matter, means, methods or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1-11. (canceled)

12. A method of manufacturing a metal-semiconductor-metal (MSM) photodetector, said method comprising:
providing in a semiconductor an oxidizing layer between a substrate and an absorbing layer of said photodetector, wherein said oxidizing layer oxidizes more quickly than either said substrate or said absorbing layer;
etching to expose said quickly oxidizing layer; and
oxidizing said quickly oxidizing layer.

13. The method of claim 12 wherein said quickly oxidizing layer is created during an epitaxial growth of said absorbing layer.

14. The method of claim 12 further comprising:
etching a mesa structure in said semiconductor which exposes said quickly oxidizing layer; and
laterally oxidizing said quickly oxidizing layer.

15. The method of claim 12 wherein said semiconductor material is GaAs.

16. The method of claim 15 wherein said quickly oxidizing layer comprises AlGaAs.

17. A method of decreasing a capacitance of a metal-semiconductor-metal photodetectors, said method comprising;
growing an absorption layer of said photodetector over a semiconductor substrate layer of said photodetector; and
providing a dielectric layer between said absorbing and said substrate layers, wherein said dielectric layer has a lower dielectric constant than said absorption layer.

18. The method of claim 17 wherein said dielectric layer is an oxide.

19. The method of claim 17 wherein said growing is one of molecular beam epitaxy, chemical vapor depositions, or metal organic vapor phase epitaxy.

20. The method of claim 17 wherein said dielectric layer has a lower index of refraction than said absorbing layer.
